(19) United States
(12) Patent Application Publication
(10) Pub. No.: US 2013/0107470 A1
(43) Pub. Date: May 2, 2013

(54) ELECTRONIC APPARATUS COMPRISING A RECESS FOR RECEIVING AN EXTERNAL MODULE

(71) Applicants: Cécile Maurech, Rueil Malmaison (FR); Stéphane Kohn, Rueil Malmaison (FR); Xavier Ferrieres, Rueil Malmaison (FR)

(72) Inventors: Cécile Maurech, Rueil Malmaison (FR); Stéphane Kohn, Rueil Malmaison (FR); Xavier Ferrieres, Rueil Malmaison (FR)

(73) Assignee: SAGEMCOM BROADBAND SAS, Rueil Malmaison (FR)

(21) Appl. No.: 13/808,882

(22) PCT Filed: Jul. 13, 2011
(86) PCT No.: PCT/EP2011/061998

§ 371 Date: Jan. 7, 2013

(30) Foreign Application Priority Data
Jul. 30, 2010 (FR) 1056356

(51) Int. Cl. H05K 5/02

(52) U.S. Cl. CPC H05K 5/0247
USPC 361/728

(57) ABSTRACT

The invention relates to electronic equipment including at least one housing shaped to receive an external module, the external module having at least one connector for co-operating with at least one complementary connector of the equipment arranged at the end of the housing when the external module is placed in the housing. According to the invention, the device includes isolation means for responding to a contactor being activated by switching off at least an electrical power supply at least for the power supply contacts of the connector of the equipment, the contactor being arranged on the equipment so as to be activated by the external module before the connectors connect together and to be deactivated once the connectors are connected together when the external module is properly in place in the housing.

The invention relates to electronic equipment including at least one housing shaped to receive an external module.

### TECHNOLOGICAL BACKGROUND OF THE INVENTION

Certain pieces of electronic equipment, such as Internet “boxes”, have one or more housings, each shaped to receive an external module. These housings are easily accessible to a user. The user can thus easily insert an external module, such as an additional hard disk, an Ethernet card, . . . , into the housing and push said external module towards the end wall of the housing until a connector of the external module co-operates with a complementary connector of the equipment, which complementary connector is located at the end of the housing.

Nevertheless, the user may forget to switch off the power supply of the electronic equipment before inserting the external module. Various problems then run the risk of arising at the moment when the connectors of the electronic equipment and of the external module make contact. For example, there may be a large inrush of current at the moment of contact between the power supply contacts of the two connectors, i.e. the contacts for powering the external module. Said contacts then run the risk of being damaged.

These problems might possibly damage the external module and/or the electronic equipment.

### OBJECT OF THE INVENTION

An object of the invention is to propose electronic equipment that includes at least one housing shaped to receive an external module and capable of protecting itself and the external module while the module is being connected to the electronic equipment.

### BRIEF DESCRIPTION OF THE INVENTION

To this end, the invention proposes electronic equipment including at least one housing shaped to receive an external module, the external module having at least one connector for co-operating with at least one complementary connector of the equipment arranged at the end of the housing when the external module is placed in the housing.

According to the invention, the device includes isolation means for responding to a contactor being activated by switching off an electrical power supply at least for the power supply contacts of the connector of the equipment, the contactor being arranged on the equipment so as to be activated by the external module before the connectors connect together and to be deactivated once the connectors are connected together when the external module is properly in place in the housing. The electronic equipment also includes at least one conductive spring blade connected to the ground of the electronic equipment and projecting into the housing, the blade being arranged to come into contact with a conductive zone of the external module before the connectors are connected together.

Since the power supply contacts of the connector of the electronic equipment are no longer powered, no power supply can pass via the connectors. The electronic equipment and the external module are thus protected automatically without any particular action on the part of the user, at the time when the connectors of the external module and of the electronic equipment make contact.

In a preferred embodiment, the isolation means are arranged to switch off at least an electrical power supply for all of the contacts of the connector of the equipment in response to the contactor being activated.

This makes it possible to avoid any risk of a signal going from the electronic equipment to the external module via contacts of the connector that are still powered. If signals go from the electronic equipment to the external module before the external module is fully connected to the equipment, it is possible to disturb or even damage integrated circuits in the electronic equipment and/or the external module.

Since all of the contacts of the connector of the electronic equipment are no longer powered, no power and no signal can pass via the connectors. The electronic equipment and the external module are thus even better protected.

### BRIEF DESCRIPTION OF THE DRAWINGS

The invention can be better understood in the light of the following description of a particular, non-limiting embodiment of the invention given with reference to the figures of the accompanying drawings, in which:

FIG. 1 is a fragmentary perspective view of electronic equipment of the invention;

FIG. 2 is a fragmentary section view of a zone of the electronic equipment shown in FIG. 1;

FIG. 3 is a perspective view of an external module designed to be inserted in the housing of the electronic equipment shown in FIG. 1;

FIG. 4 is a fragmentary perspective view of the external module shown in FIG. 3 while it is being inserted in the housing in the electronic equipment; and

FIG. 5 is a fragmentary perspective view of the external module shown in FIG. 3 when in place in the housing in the electronic equipment.

### DETAILED DESCRIPTION OF THE INVENTION

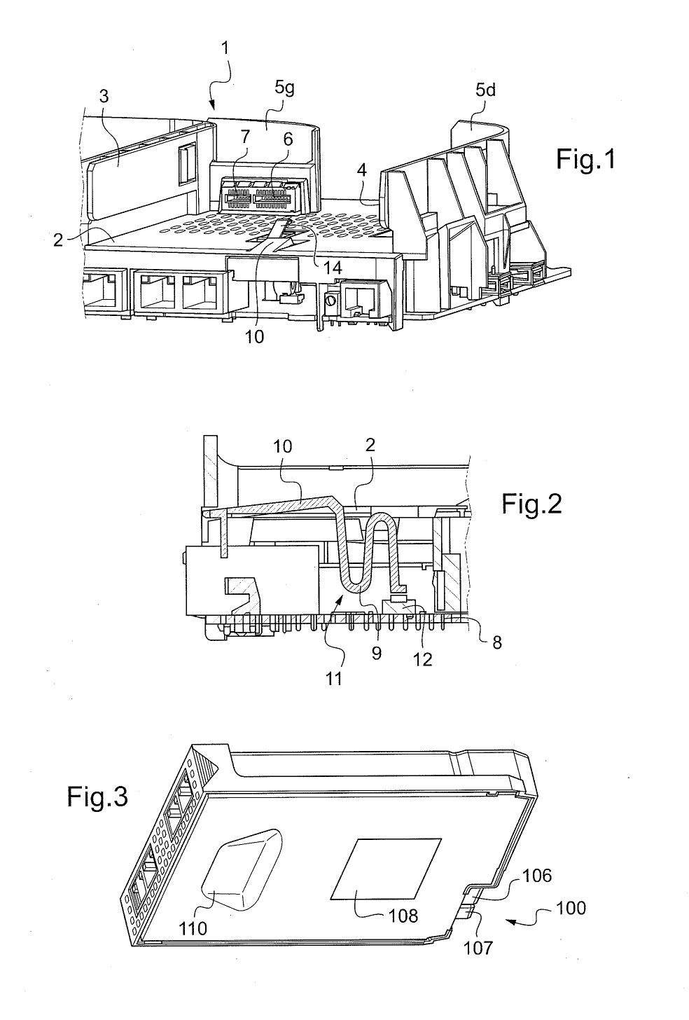

With reference to FIGS. 1 and 2, the electronic equipment of the invention is shown in this example without its cover. By way of example, the electronic equipment is an access point to the Internet or a gateway of the Internet “box” type.

In this example the electronic equipment has a housing 1 defined by:

a floor 2;

a ceiling (not shown) that is opposite to the floor 2 and that is formed by a face of the cover when the cover is in place on the electronic equipment;

two side walls 3, 4; and

a third wall forming the end wall 5 of the housing (in this example the end wall 5 of the housing is made up of two partitions: partitions 5d and 5g that are on the right and on the left in the orientation of FIG. 1).

A first connector 6 is arranged at the end wall 5 of the housing and it is connected to an electronic card 8 of the electronic equipment, which card is known as a motherboard. In this example the electronic card 8 is arranged under the floor 2 of the housing 1 and it carries electronic components serving in particular to supply electrical power to the electronic equipment. In this example a second connector 7 is also arranged at the end wall 5 of the housing close to the connector 6 and it is also connected to the electronic card 8. Both connectors 6 and 7 in this example are arranged on the left partition 5g of the end wall 5 of the housing.

In the invention, the electronic equipment includes means for isolating the electronic equipment, which means comprise a contactor 11.

In a preferred embodiment, the contactor 11 comprises an operating lever 10 that projects into the housing 1. In this example, the operating lever 10 projects from the floor 2 substantially at the entrance to the housing 1 and at equal distances from the two side walls 3 and 4. The operating lever 10 is preferably in the form of an inclined strip sloping upwards from the entrance of the housing 1 towards the end wall 5 of the housing. The contactor 11 also includes a pusher 9 associated with the operating lever 10, the pusher 9 being connected to the operating lever 10. The pusher 9 is preferably S-shaped.

The contactor 11 also has a switch 12 associated with a transistor of the electronic card 8, said transistor serving to disconnect the general electrical power supply of the electronic equipment. In this example the transistor is controlled by means of a capacitor-and-resistor circuit that serves to limit the current drawn when the transistor closes.

In the closed position, the switch 12 is connected to the ground of the electronic equipment.

The switch 12 is associated with the operating lever 10 via the pusher 9. The contactor 11 is arranged in such a manner that when it is deactivated (FIGS. 1 and 2), the pusher 9 is positioned above the switch 12 without pushing down on the switch 12. The switch 12 is then opened: the transistor is closed and the electronic equipment is powered. In addition, the contactor 11 is arranged so that when the contactor 11 is activated, i.e. when the operating lever 10 is pushed down, the pusher 9 presses on the switch 12 so as to close said switch 12. This opens the transistor which turns off the general power supply of the electronic equipment. Advantageously, the S-shape of the pusher 9 gives it a certain amount of flexibility, thereby making it easier to close the switch 12.

With reference to FIGS. 1 and 3, the housing 1 is shaped to receive an external module 100. The external module 100 has two connectors 106 and 107 that are complementary respectively to the connectors 6 and 7 of the electronic equipment so that when the external module 100 is in place in the housing 1, the connectors 106 and 107 of the external module 100 co-operate respectively with the connectors 6 and 7 of the electronic equipment. In the invention, the external module 100 includes a setback 110 in one of its outside walls that is to come into contact with the floor 2 of the housing 1.

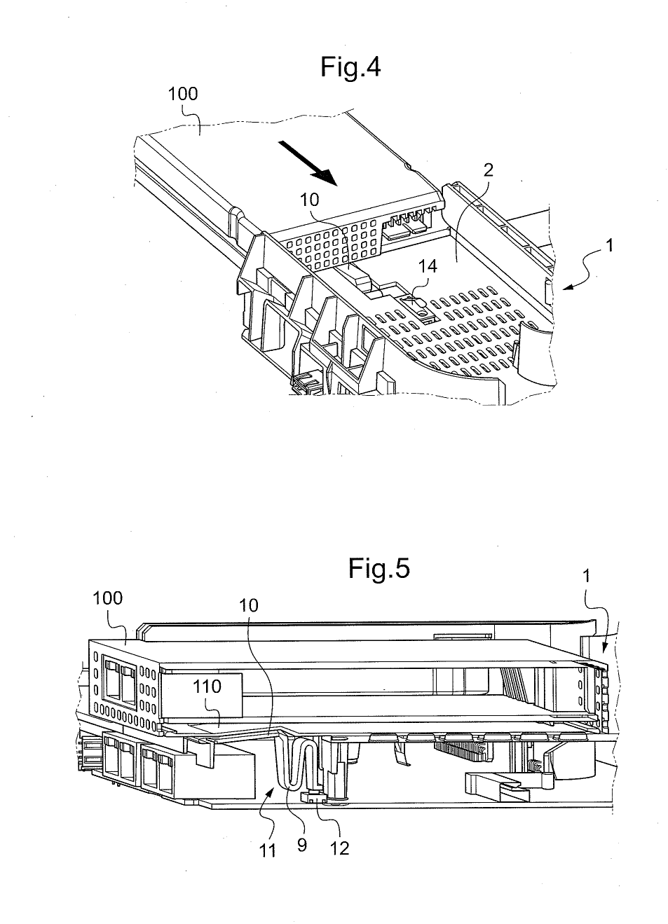

With reference to FIGS. 4 and 5, the external module 100 is put into place in the housing 1 as follows. When the housing 1 is empty, the contactor 11 is deactivated. The electronic equipment is thus powered.

When a user inserts the external module 100 into the housing 1, the outside wall with the setback 110 slides over the floor 2 of the housing 1 as represented by the arrow. Very quickly, the external module 100 comes up to the operating lever 10. If the user continues to push the external module 100 into the housing 1, then a portion of the outside wall of the external module 100 pushes down the operating lever 10, thereby activating the contactor 11. Advantageously, the sloping strip shape of the operating lever 10 makes it easier for the external module 100 to operate the operating lever 10. The operating lever 10 in turn pushes down the pusher 9, which then presses against the switch 12. The switch 12 closes, thereby switching off the general power supply to the electronic equipment by means of the transistor.

The user continues to push on the external module 100 until it is in place in the housing, specifically until the connectors of the external module 100 and of the electronic equipment are connected together. The setback 110 is shaped so that when the external module 100 is in place in the housing 1, the operating lever 10 is released.

By simple isolation means, it is thus possible to switch off the power supply of the contacts in the connectors 6, 7 of the electronic equipment for the time it takes the external module 100 to be connected to the electronic equipment via the complementary connector pairs 6 & 106 and 7 & 107.

Advantageously, the isolation means operate reversibly. As soon as the user pulls on the external module 100 in order to extract it from the housing 1, the operating lever 10 is pushed down. The power supply to the electronic equipment is once more switched off, with this taking place before the connectors of the electronic equipment and of the external module 100 are totally separated. The contactor 11 returns to its rest position only once the connectors of the electronic equipment and the external module 100 are separated.

In a preferred embodiment, in order to facilitate connecting the ground of the external module 100 to the ground of the electronic equipment, the electronic equipment also includes a conductive spring blade 14 that is directly connected to the ground of the electronic equipment and that projects into the housing 1. The blade 14 is designed to make contact with a conductive zone 108 of the external module 100 when it is in place in the housing. The blade 14 is arranged in the housing 1 in such a manner that when the blade 14 comes into contact with the conductive zone. 108, the connectors 6 and 7 of the electronic equipment and the connectors 106 and 107 of the external module 100 are not yet in co-operation.

If the external module 100 has a ground that is different from that of the electronic equipment at the time the external module 100 is inserted in the electronic equipment, it is possible for an electrostatic discharge to take place at the moment when the connectors make contact. Semiconductors of the electronic equipment and/or of the external module 100 then run the risk of being destroyed. The blade 14 thus serves to avoid this possible electrostatic discharge.

The invention is not limited to the embodiment described and embodiment variants may be applied thereto without going beyond the ambit of the invention as defined by the claims.

In particular, the invention is arranged specifically to make it possible during connection to avoid making contact between two connector elements that are subjected to different potentials. Although the general electrical power supply to the electronic equipment in this example is switched off for the time it takes to make the connection with the external module, provision could be made to switch off the power supply of the electronic equipment only locally, providing the power supply is switched off at least to the connector of the equipment. Preferably, the isolation means are arranged to switch off at least an electrical power supply for all of the contacts of the connector of the equipment in response to the contactor being activated.

In addition, the electronic equipment may have more than one housing shaped to receive an external module. The isolation means could thus switch off the power supply of the electronic equipment locally in each housing or else could switch off the general power supply for the electronic equipment.

The electronic equipment may include any other number of connectors.

Although the contactor 11 has an operating lever 10 that projects from the floor 2 substantially at the entrance to the housing 1 and at equal distances from the two side walls 3 and 4, it is possible to envisage placing the operating lever 10 at some other location in the housing 1 providing the operating lever 10 can be activated before the connectors 6, 7 of the electronic equipment and the connectors 106 and 107 of the external module come into contact. Nevertheless, it is simpler to place the operating lever in the floor 2 since the electronic card 8 lies under said floor.

Although the isolation means of the electronic equipment in this example are mechanical means, it is possible to envisage having recourse to other types of isolation means. For example, the isolation means could include an optical contactor in which the emitter element is arranged at the entrance of the housing 1 on one of the side walls, the emitter element emitting a light beam to a receiver element that faces it on the opposite side wall. When the external module 100 is inserted in the housing 1, it interrupts the light beam emitted from the emitter element to the receiver element and the optical contactor is thus activated. It is also possible to envisage that the isolation means are not hardware means. Software might thus be arranged to switch off the electrical power supply of the electronic equipment in response to a contactor being activated.

What is claimed is:

1. Electronic equipment including at least one housing shaped to receive an external module, the external module having at least one connector for co-operating with at least one complementary connector of the equipment arranged at the end of the housing when the external module is placed in the housing, the device including isolation means for responding to a contactor being activated by switching off an electrical power supply at least for the power supply contacts of the connector of the equipment, the contactor being arranged on the equipment so as to be activated by the external module before the connectors connect together and to be deactivated once the connectors are connected together when the external module is properly in place in the housing, wherein the electronic equipment also includes at least one conductive spring blade connected to the ground of the electronic equipment and projecting into the housing, the blade being arranged to come into contact with a conductive zone of the external module before the connectors are connected together.

2. The electronic equipment according to claim 1, wherein the isolation means are arranged to switch off at least an electrical power supply for all of the contacts of the connector of the equipment in response to the contactor being activated.

3. The electronic equipment according to claim 1, wherein the isolation means are arranged to switch off a general power supply of the equipment in response to the contactor being activated.

4. The electronic equipment according to claim 1, wherein the contactor comprises a switch, the switch being associated with an operating lever that projects into the housing so as to be operated by a portion of an outside wall of the module.

5. The electronic equipment according to claim 4, wherein the operating lever is associated with a pusher that presses selectively against the switch, the pusher being S-shaped.

6. The electronic equipment according to claim 1, wherein the contactor is arranged to be activated during removal of the module before the connectors are separated, and to be deactivated once the connectors have separated.
